(19) United States
(12) Patent Application Publication
(10) Pub. No.: US 2014/0117416 A1
(43) Pub. Date: May 1, 2014

(54) SEMICONDUCTOR DEVICE AND ASSOCIATED METHOD FOR MANUFACTURING

(71) Applicant: Chengdu Monolithic Power Systems Co., Ltd., Chengdu (CN)

(72) Inventors: Lei Zhang, Chengdu (CN); Tiesheng Li, San Jose, CA (US); Rongyao Ma, Chengdu (CN); Daping Fu, Chengdu (CN)

(21) Appl. No.: 14/069,293

(22) Filed: Oct. 31, 2013

(30) Foreign Application Priority Data
Oct. 31, 2012 (CN) 201210426365.1

(51) Int. Cl. H01L 27/088; H01L 29/66

(52) U.S. Cl. CPC H01L 27/088; H01L 29/66893
USPC 257/262; 438/192

(57) ABSTRACT

A semiconductor device having a trench-gate MOSFET and a vertical JFET formed in a semiconductor layer. In the semiconductor device, a gate region of the vertical JFET may be electrically coupled to a source region of the trench-gate MOSFET, and a drain region of the vertical JFET and a drain region of the trench-gate MOSFET may share a common region in the semiconductor layer.

### CROSS-REFERENCE TO RELATED APPLICATION(S)

This application claims the benefit of CN application No. 201210426365.1 filed on Oct. 31, 2012 and incorporated herein by reference.

### TECHNICAL FIELD

The present invention generally relates to semiconductor devices, and more particularly but not exclusively relates to a semiconductor device having vertical trenches and associated fabricating processes.

### BACKGROUND

Integrated circuits with fewer pins are generally desirable, because fewer pins need fewer external elements in practical application configuration, which means cost and size saving when implemented on a printed circuit board (“PCB”).

According to this requirement, in certain applications, external power sources provided to supply an integrated circuit (“IC”) are usually configured to supply a drain of a power transistor, e.g. a Metal Oxide Semiconductor Field Effect Transistor (“MOSFET”), of the IC, and are generally undesirable to supply other internal circuits of the IC. In such applications, the power transistor functions not only as a switch of the IC system but also as a power supply for the other internal low voltage circuits in the IC. For such kind of ICs, it is therefore desired that the power transistor can prevent a high voltage supplied to the drain of the power transistor from reaching the other low voltage internal circuits to protect the low voltage internal circuits.

### SUMMARY

In one embodiment, the present invention discloses a semiconductor device. The semiconductor device may comprise: a semiconductor layer of a first conductivity type; and a trench-gate MOSFET and a vertical JFET formed in the semiconductor layer. The trench-gate MOSFET comprises: a trenched gate region formed in the semiconductor layer, the trenched gate region including a gate trench filled with a gate dielectric layer and a gate conductive layer; a source region of the first conductivity type formed in the semiconductor layer near the trenched gate region; and a drain region of the first conductivity type formed in the semiconductor layer. The vertical JFET comprises: a gate region formed in the semiconductor layer, wherein the gate region includes a trench and a doped region of a second conductivity type opposite to the first conductivity type formed below the trench; a source region of the first conductivity type formed in the semiconductor layer; and a drain region of the first conductivity type formed in the semiconductor layer; and wherein the gate region of the vertical JFET is electrically coupled to the source region of the trench-gate MOSFET.

In one embodiment, the present invention further discloses a method for fabricating a semiconductor device. The method comprises: forming a gate trench of a trench-gate MOSFET and forming a trench of a vertical JFET in a semiconductor layer of a first conductivity type; forming a doped region of a second conductivity type opposite to the first conductivity type surrounding and contacting a bottom of the trench of the vertical JFET; forming a gate region of the trench-gate MOSFET by filling the gate trench with a gate dielectric layer and a gate conductive layer, and a gate region of the vertical JFET by filling the trench; forming a source region of the first conductivity type of the trench-gate MOSFET and a source region of the first conductivity type of the vertical JFET in the semiconductor layer; forming a drain region of the first conductivity type of the trench-gate MOSFET and a drain region of the first conductivity type of the vertical JFET in the semiconductor layer; and wherein, the gate region of the vertical JFET is electrically coupled to the source region of the trench-gate MOSFET in the semiconductor layer.

### BRIEF DESCRIPTION OF THE DRAWINGS

Non-limiting and non-exhaustive embodiments are described with reference to the following drawings. The drawings are only for illustration purpose. Usually, the drawings only show part of the system or circuit of the embodiment, and the same reference label in different drawings have the same, similar or corresponding features or functions.

FIG. 1 schematically shows a cross-sectional view of a semiconductor device according to an embodiment of the present invention.

FIG. 2 schematically shows an equivalent symbolic circuit diagram of the semiconductor device in FIG. 1 according to an embodiment of the present invention.

FIGS. 3A-3F schematically show cross-sectional views illustrating a method of fabricating a semiconductor device according to an embodiment of the present invention.

FIG. 4 schematically shows a cross-sectional view of a semiconductor device according to an alternative embodiment of the present invention.

FIG. 5 schematically shows a cross-sectional view of a semiconductor device according to an alternative embodiment of the present invention.

### DETAILED DESCRIPTION

The embodiments of the present invention are described in the next. While the invention will be described in conjunction with various embodiments, it will be understood that they are not intended to limit the invention to these embodiments. On the contrary, the invention is intended to cover alternatives, modifications and equivalents, which may be included within the spirit and scope of the invention as defined by the appended claims. Furthermore, in the following detailed description of the embodiments of the present invention, numerous specific details are set forth in order to provide a thorough understanding of the embodiments of the present invention. However, it will be obvious to one of ordinary skill in the art that without these specific details the embodiments of the present invention may be practiced. And it should be noted that well-know circuits, materials, and methods are not described in detail so as not to unnecessarily obscure aspect of the embodiments of the present invention.

In the specification and appended claims, “on”, “in”, “into” “onto”, “below”, “on the top of”, “in the front of”, “right”, “left” and/or the like terms may be employed to describe relative positions of related elements, but not to add absolute restrictions to the elements. For example, when one layer is described “on” the other layer, it means one layer may be located on the other one directly, or additional layers may exist between them. Though “region” or “regions”, “trench” or “trenches”, “pad” or “pads” and other similar terms are referred to in the description with singular or plural forms, it is not confined to the singular or plural numbers, and any number is considered in the embodiments. The semiconductor device may comprise a field effect transistor, a bipolar junction transistor and/or other similar devices, thus, the “gate/gate region”, “source/source region”, and “drain/drain region” may comprise “base/base region”, “emitter/emitter region”, and “collector/collector region” respectively, and may further comprise structures similar as the “gate/gate region”, “source/source region”, and “drain/drain region”.

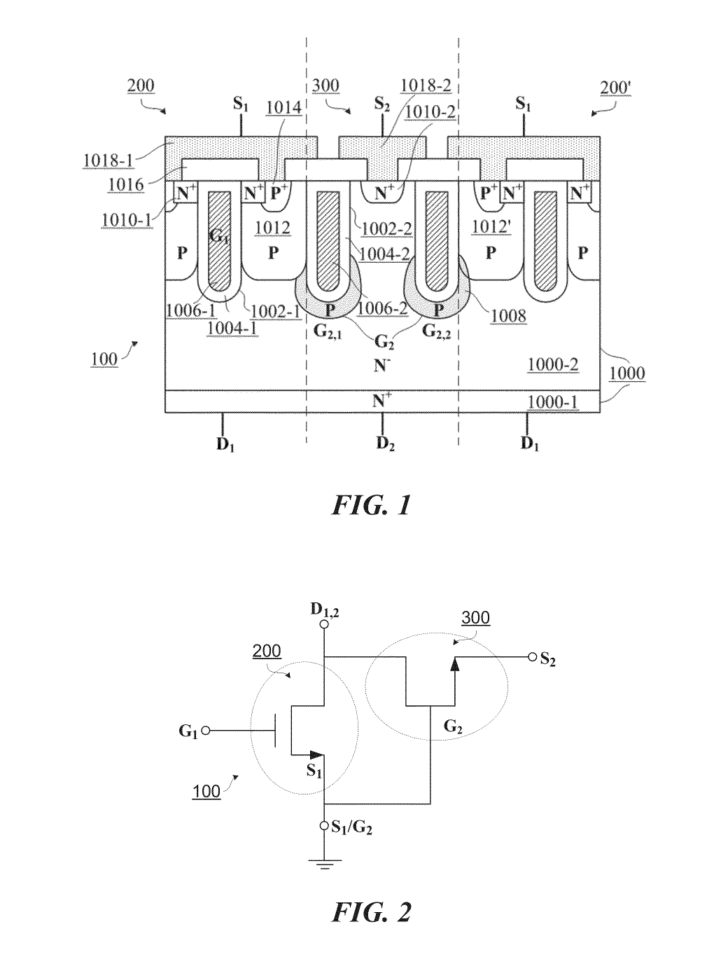

FIG. 1 shows a cross-sectional view of a semiconductor device 100. The semiconductor device 100 may comprise a MOSFET 200 and a JFET 300 formed on a semiconductor layer 1000. In some embodiments, MOSFET 200 may comprise a trench-gate MOSFET, and JFET 300 may comprise a vertical JFET, which could easily be integrated together. As shown in FIG. 1, the semiconductor layer 1000 may comprise a substrate 1000-1 of a first conductivity type (e.g. N+ type) and having a heavy dopant concentration, and an epitaxial layer 1000-2 of the first conductivity type (e.g. N− type) and having a relatively light dopant concentration compared to the substrate 1000-1. However, this is not intended to be limiting. The semiconductor layer 1000 may comprise doped silicon (Si), Silicon-Germanium (SiGe), Silicon on insulator (SOI) and/or any other suitable semiconductor materials.

It should be noted that in the embodiment illustrated in FIG. 1, the dotted line in vertical orientation between the MOSFET 200 and the JFET 300 indicates approximate boundaries between them rather than absolute boundaries.

MOSFET 200 may comprise a gate region G₁, a source region S₁ and a drain region D₁. In the exemplary embodiment where the MOSFET 200 is a trench-gate MOSFET, the gate region G₁ may comprise a trenched gate region formed in the semiconductor layer, e.g., in the N− epitaxial layer 1000-2 illustrated in FIG. 1. In one embodiment, trenched gate region G₁ may comprise a gate dielectric layer 1004-1 and a gate conductive layer 1006-1 formed in a gate trench 1002-1. For example, the gate dielectric layer 1004-1 may comprise SiO2, and the gate conductive layer 1006-1 may comprise polysilicon. Laterally adjacent to the gate region G₁, a body region 1012 of a second conductivity type (e.g. P type) opposite to the first conductivity type is formed in the N− epitaxial layer 1000-2 shown in FIG. 1. Source region S₁ may comprise a heavy doped source region 1010-1 of the first conductivity type (e.g., N+ type) formed in an upper portion of the body region 1012. N+ substrate 1000-1 may function as the drain region D₁ of the MOSFET 200.

JFET 300 may comprise a gate region G₂, a source region S₂ and a drain region D₂. In the exemplary embodiment where the JFET 300 is a vertical JFET, the gate region G₂ may comprise a first portion (a left portion) G_{2, 1} and a second portion (a right portion) G_{2, 2}. In the embodiment of FIG. 1, each of the left portion G_{2, 1} and the right portion G_{2, 2} may comprise a doped region 1008 of the second conductivity type (e.g. P type) formed below a trench 1002-2. In one embodiment, the doped region 1008 may be disposed surrounding a bottom of the trench 1002-2 and contacting the bottom of the trench 1002-2 as shown in FIG. 1. The trench 1002-2 may include a trench filling having the same structure as that of the gate trench 1002-1. For example, the trench filling of the trench 1002-2 may comprise a dielectric layer 1004-2 (e.g., SiO₂) and a conductor layer 1006-2 (e.g., polysilicon). In this example, filling the trench 1002-2 of the JFET 300 can be implemented with the same processes for fabricating the gate region G₁ of the MOSFET 200, which facilitates the integration of the MOSFET 200 and the JFET 300. The source region S₂ may comprise a heavy doped source region 1010-2 of the first conductivity type e.g., N+ type formed at the topside of the N− epitaxial layer 1000-2 illustrated in FIG. 1. The source region 1010-2 of the JFET 300 and the source region 1010-1 of the MOSFET 200 may be configured to have a substantially same structure so as to be fabricated in same processes, which may also be beneficial to integration of the MOSFET 200 and the JFET 300. N+ substrate 1000-1 can also be operated as a drain region D₂ of the JFET 300. Therefore, the MOSFET 200 and the JFET 300 share a same drain (i.e. N+ substrate 1000-1), in other words, the MOSFET 200 and the JFET 300 may comprise a common drain region.

It should be understood that, although the gate region G₂ of the JFET 300 are illustrated as two separated portions G_{2, 1} and G_{2, 2} in the sectional view of FIG. 1, the left portion G_{2, 1} and the right portion G_{2, 2} could be electrically connected actually. For example, the left portion G_{2, 1} and the right portion G_{2, 2} of the gate region G₂ are electrically coupled via a transverse trenched connection portion (not shown in the sectional view of FIG. 1) in the semiconductor layer 1000.

In the various embodiments described above, both MOSFET 200 and JFET 300 are configured as vertical devices, therefore, the MOSFET 200 and the JFET 300 share a common substrate (i.e. the substrate 1000-1) as their drain regions respectively.

In addition, as shown in FIG. 1, the left portion G_{2, 1} and/or the right portion G_{2, 2} of the gate region G₂ of the JFET 300 may at least partially overlap the body region 1012 of the MOSFET 200, so that the gate region G₂ of the JFET 300 can be electrically coupled/connected to the source region S₁ of the MOSFET 200 in the epitaxial layer 1000-2. In the exemplary embodiment in FIG. 1, the doped region 1008 of the gate region G2 of the JFET 300 may at least partially overlap the body region 1012 of the MOSFET 200.

In one embodiment of the present invention, an interlayer dielectric layer (IDL) 1016 may be formed onto the surface of the epitaxial layer 1000-2 and be patterned to form contact vias. Following, a metal layer may be formed onto the IDL 1016. The metal layer can be patterned to form a source metal layer 1018-1 of the MOSFET 200 and a source metal layer 1018-2 of the JFET 300, which can be respectively coupled to the source region 1010-1 of the MOSFET 200 and the source region 1010-2 of the JFET 300 through the contact vias in the IDL 1016. A high/heavy doped body contact region 1014 of the second conductivity type (e.g. P type) may be formed in the body region 1012 below the contact vias so that the body region 1012 can electrically better connected to the source metal 1018-1.

In one embodiment of the present invention, still referring to FIG. 1, another MOSFET 200′ having a same structure as that of the MOSFET 200 may be formed next to (e.g. on the right side) of the JFET 300. In this example, the left portion G_{2, 1} and the right portion G_{2, 2} of gate region G₂ in the JFET 300 can be electrically coupled in another way. For example, the left portion G_{2, 1} and the right portion G_{2, 2} of gate region G₂ can contact the adjacent body region 1012 of the MOSFET 200 and body region 1012 of the MOSFET 200′ respectively. The source region S₁ of the MOSFET 200 and the source region S₁ of the MOSFET 200′ may be coupled to each other through the source metal 1018-1, therefore, the left portion G_{2, 1} and the right portion G_{2, 2} are electrically coupled to the source regions S₁ of the MOSFETs 200 and 200′.

FIG. 2 schematically shows an equivalent symbolic circuit diagram of the semiconductor device shown in FIG. 1 according to an embodiment of the present invention. As shown in FIG. 2, the equivalent symbolic circuit diagram has four terminals D_{1, 2}, S₂, S₁/G₂, G₁. The terminal D_{1, 2} operates as the common drain region of the MOSFET 200 and the JFET 300 and can be configured to receive an external power supply. The terminal S₂ operates as the source region of the JFET 300 and may be configured to supply for internal low voltage circuits of an IC which includes the semiconductor device shown in FIGS. 1 and 2. The terminal S₁/G₂ operates as the common connection of the source region of the MOSFET 200 and the gate region of the JFET 300 and can be configured to connect to a reference potential, illustrated in the example of FIG. 2 as a reference ground. The terminal G₁ operates as the gate region of the MOSFET 200 and can be configured to receive a control signal. In operation, a channel formed between the left portion G_{2, 1} and the right portion G_{2, 2} of the gate region G2 may be pinched off once the voltage of the terminal D_{1, 2} exceeds a predetermined/designed pinch-off voltage of the JFET 300. Thus, the JFET 300 may be turned off to prevent the high voltage of the terminal D_{1, 2} to arrive to the internal low-voltage circuit. The predetermined/designed pinch-off voltage can be appropriately modified accordingly to practical requirements (e.g. the pinch-off voltage should be lower than or equal to a maximum rated voltage of the internal circuits supplied by the source terminal S₂ of the JFET 300) by regulating the space between the left portion G_{2, 1} and the right portion G_{2, 2}, optimizing the width of the left portion G_{2, 1} and the right portion G_{2, 2}, and/or regulating the width of each trench 1002-2, etc.

It should be noted that, the connection of terminal G₁ illustrated in the example as the gate of the MOSFET 200 is not shown in FIG. 1, but the terminal G₁ may be connected to a gate metal (not shown in the sectional view of FIG. 1) by a groove connection part (not shown in the sectional view of FIG. 1) in the semiconductor layer 1000.

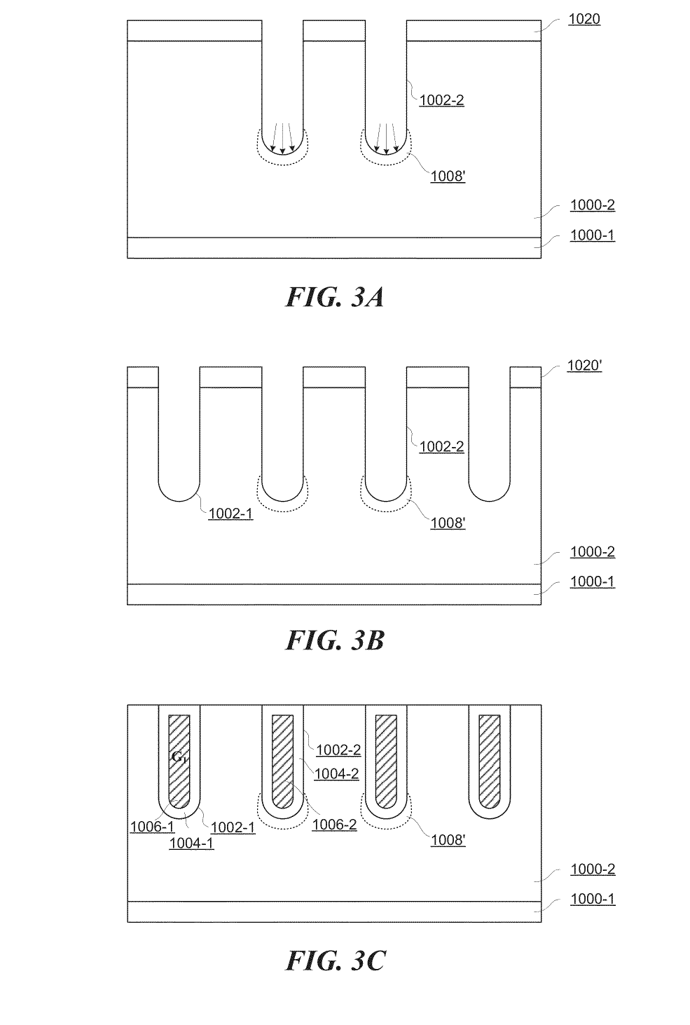

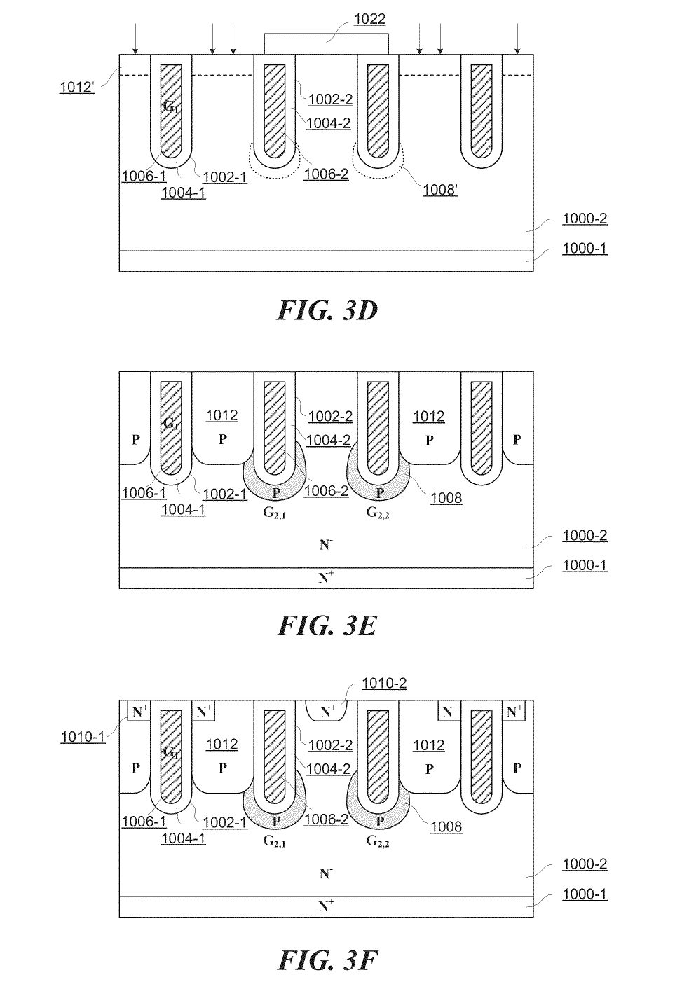

FIGS. 3A-3F illustrate a method of fabricating the semiconductor device 100 of FIG. 1. As the embodiment in FIG. 3A shown, the semiconductor device 100 may comprise a heavy doped substrate 1000-1 of a first conductivity type (e.g. N+ type) and a light doped epitaxial layer 1000-2 of the first conductivity type (e.g. N− type) formed on the substrate 1000-1. A mask layer 1020 may be deposited on the epitaxial layer 1000-2 and then patterned based on the number of the JFETs (such as the JFET 300) that is desired/designed. In FIG. 3A, although mask layer 1020 is exemplarily patterned for forming one JFET 300, this is not intended to be limiting. In other embodiment, any suitable number of JFETs may be employed. In one embodiment, the mask layer 1020 may comprise a hard mask (e.g. nitride) and/or a soft mask (e.g. photoresist). Following patterning of the mask layer 1020, the epitaxial layer 1000-2 may be etched to form trench/trenches 1002-2. In one embodiment, etching epitaxial layer 1000-2 may include a reactive ion etching (RIE) process. The etching process may also be performed to etch the trench/trenches 1002-2 of any suitable depth and/or width. As illustrated by the arrow in FIG. 3A, ions of a second conductivity type may be implanted into the epitaxial layer 1000-2 through the trench/trenches 1002-2 by an ion implantation process to form an ion doped region 1008′. In one embodiment, P-type ions (e.g. Boron ions) may be implanted into the epitaxial layer 1000-2.

As shown in FIG. 3B, the mask layer 1020 may further be patterned to a mask layer 1020′ based on the number of gate regions of the MOSFETs (such as the MOSFET 200) that is desired/designed. In the exemplary embodiment of FIG. 3B, although mask layer 1020′ is exemplarily patterned for forming two MOSFETs 200, this is not intended to be limiting. In other embodiment, any suitable number of MOSFETs may be formed. Gate trench/trenches 1002-1 of any suitable depth and/or width may then be formed in the epitaxial layer 1000-2 by an etching process. In one embodiment, etching the epitaxial layer 1000-2 may include a reactive ion etching (RIE) process. After forming the gate trench/trenches 1002-1, the mask layer 1020′ is removed. In other embodiment, the mask layer 1020 is removed after formation of the trench/trenches 1002-2 and an additional thick mask layer 1020′ may be formed on the epitaxial layer 1000-2 so as to prevent the existed trench/trenches 1002-2 from being further etched during forming the gate trench/trenches 1002-1.

In another embodiment, the mask layer 1020 may be omitted, the mask layer 1020′ may be patterned according to the patterns and the number of the gate trenches 1002-1 of the MOSFETs 200 and the trenches 1002-2 of the JFETs 300 that are needed so as to form the gate trench/trenches 1002-1 and the trench/trenches 1002-2 in a same step. Then the mask layer 1020′ is removed after formation of the gate trenches 1002-1 and the trenches 1002-2. In the following, an additional mask layer may be employed for shielding portions of the semiconductor layer (including the gate trenches 1002-1) that are designated for forming the MOSFETs 200 so that ions of the second conductivity type are implanted into the semiconductor layer through the unshielded trench/trenches 1002-2 to form the ion doped region 1008′.

In the following, referring to FIG. 3C, the gate trench/trenches 1002-1 and the trench/trenches 1002-2 may be filled with trench fillings. In one embodiment, the gate trench/trenches 1002-1 and the trench/trenches 1002-2 may be filled with trench fillings of same materials. For example, a gate dielectric layer 1004-1 may be grown onto the sidewalls of the gate trench/trenches 1002-1 and a dielectric layer 1004-2 may be grown onto the sidewalls of the trench/trenches 1002-2 respectively by a deposition and an etching process. The gate dielectric layer 1004-1 and the dielectric layer 1004-2 may comprise a same dielectric material such as silicon dioxide (SiO₂). In the exemplary embodiment where the gate dielectric layer 1004-1 and the dielectric layer 1004-2 comprise oxide, the oxide may be grown by a thermal oxidation process. After formation of the gate dielectric layer 1004-1 and the dielectric layer 1004-2, a gate conductive layer 1006-1 and a conductive layer 1006-2 may be deposited in the gate trench/trenches 1002-1 and the trench/trenches 1002-2 respectively. And then, the superfluous of the gate conductive layer 1006-1 and the conductive layer 1006-2 may be removed through a planarization process, e.g. Chemical Mechanical Polishing (CMP). In one embodiment, the gate conductive layer 1006-1 and the conductive layer 1006-2 may comprise a same conductive material such as polysilicon. Usually, the top of the polysilicon may be oxidized to form silicon oxide so that the polysilicon may be surrounded by oxides as illustrated by FIG. 3C. In addition, the surface of epitaxial layer 1000-2 may be oxidized to form a film which is not shown in the FIG. 3C for simplicity.

The gate dielectric layer 1004-1 and the gate conductive layer 1006-1 formed in the gate trench/trenches 1002-1 may function as the gate region G₁ of the MOSFET 200. The trench/trenches 1002-2 and a doped region 1008 (shown in FIG. 3E) may function as the gate region G₂ of the JFET 300, wherein the doped region 1008 may be formed by diffusing the ion doped region 1008′, and wherein the trench/trenches 1002-2 can assist in locating the gate region G₂ of the JFET 300. Therefore, trench filling of the trench/trenches 1002-2 may comprise any suitable materials other than the same as that of the gate region G₁ of the MOSFET 200. In one embodiment, the trench/trenches 1002-2 of JFET 300 comprises a trench filling having a same configuration as that of the gate trench/trenches 1002-1 of MOSFET 200 so that the trench filing can be fabricated in a same process illustrated by the FIG. 3C, thus the fabrication process of the semiconductor can be simplified.

In the following, a mask layer 1022 may be formed on the top of the JFET 300 for shielding especially a channel region between the trenches 1002-2 of the JFET 300 illustrated by the FIG. 3D. A doped body region 1012′ may then be formed via implanting ions of the second conductive into the epitaxial layer 1000-2.

Subsequently, the doped body region 1012′ may be diffused to form a body region 1012 and the ion doped region 1008′ may be diffused to form the doped region 1008 by an implantation process illustrated as FIG. 3E. In one embodiment, a heat treatment process (e.g., annealing) may be performed after the implantation process. In the following, source region may be formed illustrated by FIG. 3F, for example, the first conductive type (e.g. N+ type) ions may be diffused in the epitaxial layer 1000-2 to form a source region 1010-1 of MOSFET 200 and a source region of 1010-2 of JFET 300 respectively.

An interlayer dielectric layer (e.g. the interlayer dielectric layer 1016 illustrated in FIG. 1) and a metal layer such as the source metal 1018-1 of the MOSFET 200 and the source metal 1018-2 of the JFET 300 illustrated in FIG. 1 may be fabricated next by conventional processes. After formation and patterning the interlayer dielectric layer, contact vias may be fabricated and the body contact region (e.g. the body contact region 1014 illustrated in FIG. 1) may be formed through the contact vias by a self-aligned process.

Comparing with the conventional method of fabrication a trench-gate MOSFET, the methods of fabricating a semiconductor device illustrated by FIGS. 3A-3F only add the steps shown in FIG. 3A, i.e. forming the trench/trenches 1002-2 of JFET 300 by employing the mask layer 1020 and implanting ions through the trench/trenches 1002-2. Therefore, integration of a MOSFET and a JFET can be achieved by simple processes.

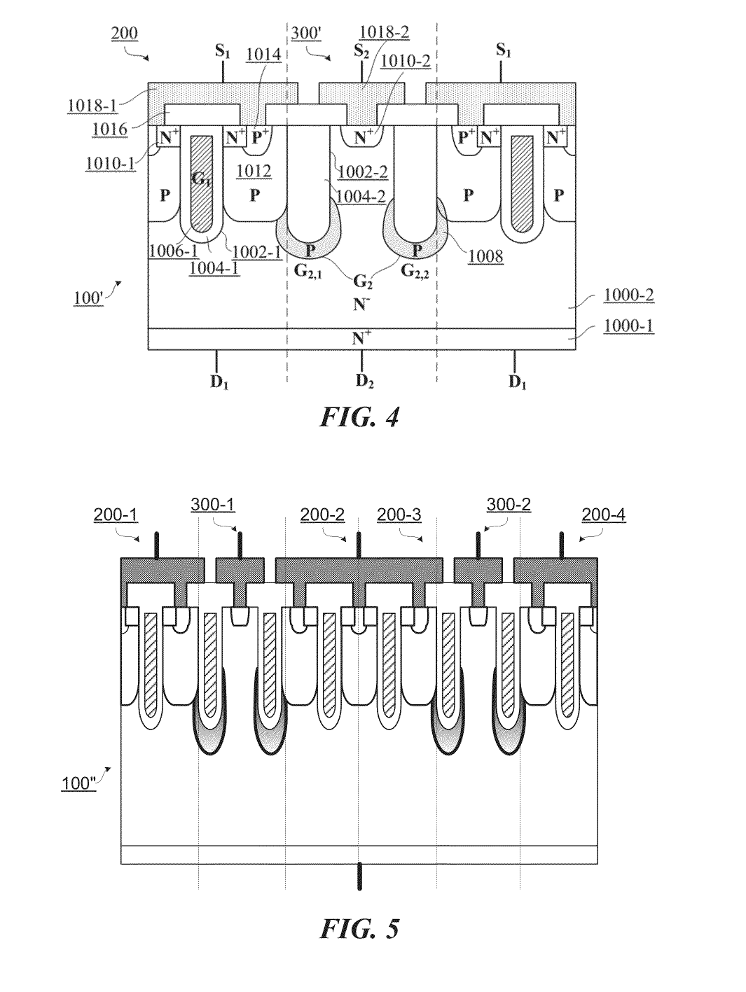

FIG. 4 schematically shows a cross-sectional view of a semiconductor device 100′ according to an alternative embodiment of the present invention. Comparing with the semiconductor device 100 illustrated in FIG. 1, the trench filling of the trench/trenches 1002-2 of JFET 300′ may be different from that of the gate trench/trenches 1002-1 of MOSFET 200 in semiconductor device 100′ as illustrated by FIG. 4. In one embodiment, the trench/trenches 1002-2 may be filled with a dielectric material, e.g. silicon dioxide (SiO2), to enhance source-gate breakdown voltage of the JFET 300′.

The semiconductor device 100′ illustrated in FIG. 4 may be fabricated by the same processes as shown by FIGS. 3A-3F, except the process shown in FIG. 3C, i.e., the dielectric layer deposited in the trench/trenches 1002-2 may be shielded during etching the dielectric layer deposited in the gate trench/trenches 1002-1 for forming the gate dielectric layer 1004-1. However, it should be noted that other available process can be adopted to substitute for the person skilled in this art.

FIG. 5 schematically shows a cross-sectional view of a semiconductor device 100″ according to an alternative embodiment of the present invention. As shown in FIG. 5, the semiconductor device 100″ may comprise a plurality of MOSFETs 200-1,200-2, 200-3, 200-4 and a plurality of JFETs 300-1 and 300-2 in a semiconductor layer of the device. Each of the MOSFETs 200-1, 200-2, 200-3 and 200-4 may comprise a same structure as that of the MOSFET 200, and each of the JFETs 300-1 and 300-2 may comprise a same structure as that of the JFET 300 illustrated by FIG 1. The plurality of MOSFETs and JFETs may be coupled to each other and the number of which can be adjusted according to the different applications.

In the above description, doped types, dose and others parameters of the impurity may not be described, which can be chosen by the ordinary person skilled in this art according to the desired applications.

The embodiments shown in the FIGS. 1-5 relates to integration of N-channel trench-gate MOSFET and N-channel vertical JFET, however, P-channel trench-gate MOSFET and P-channel vertical JFET, N-channel or P-channel DMOS, N-channel or P-channel BJT and/or the like semiconductor materials are also considered in the present technology. Although the technology described herein is applicable to devices with N type substrate materials, the P type substrate materials can also be employed. For a P type device, the dopant types are opposite to an N type device which is obvious to the ordinary person skilled in this art.

While various embodiments have been described above, it should be understood that they have been presented by way of example only, and not limitation. Thus, the breadth and scope of a preferred embodiment should not be limited by any of the above-described exemplary embodiments, but should be defined only in accordance with the following claims and their equivalents.

I/We claim:

1. A semiconductor device, comprising:
a semiconductor layer of a first conductivity type; and
a trench-gate MOSFET and a vertical JFET formed in the semiconductor layer, wherein,
the trench-gate MOSFET comprises:
a trenched gate region formed in the semiconductor layer, the trenched gate region including a gate trench filled with a gate dielectric layer and a gate conductive layer;
a source region of the first conductivity type formed in the semiconductor layer near the trenched gate region; and
a drain region of the first conductivity type formed in the semiconductor layer;
and wherein, the vertical JFET comprises:
a gate region formed in the semiconductor layer, wherein the gate region includes a trench and a doped region of a second conductivity type opposite to the first conductivity type formed below the trench;
a source region of the first conductivity type formed in the semiconductor layer; and
a drain region of the first conductivity type formed in the semiconductor layer;
and wherein, the gate region of the vertical JFET is electrically coupled to the source region of the trench-gate MOSFET.

2. The semiconductor device of claim 1, wherein the drain region of the trench-gate MOSFET and the drain region of the vertical JFET comprise a common region in the semiconductor layer.

3. The semiconductor device of claim 1, wherein,
the semiconductor layer comprises a substrate having a heavy dopant concentration of the first conductivity type and an epitaxial layer having a light dopant concentration of the first conductivity type;
the drain region of the trench-gate MOSFET and the drain region of the vertical JFET comprise the substrate;
the gate region of the vertical JFET comprises a doped region of the second conductivity type formed in the epitaxial layer; and the source region of the vertical JFET comprises a doped source region of the first conductivity type formed at a topside of the epitaxial layer;
the trench-gate MOSFET comprises a body region of the second conductivity type formed adjacent to the trenched gate region in the epitaxial layer, wherein the source region of the MOSFET comprises a doped source region of the first conductivity type formed at a topside of the body region; and wherein,
the gate region of the vertical JFET at least partially overlaps the body region so as to be electrically coupled to the source region of the trench-gate MOSFET.

4. The semiconductor device of claim 1, wherein the gate region of the vertical JFET comprises a first portion and a second portion, and wherein each of the first portion and the second portion includes said trench and said doped region, and wherein said doped region is disposed surrounding and contacting a bottom of said trench, and wherein the source region of the vertical JFET is formed between the first portion and the second portion.

5. The semiconductor device of claim 1, wherein the trench of the vertical JFET comprises a trench filling having the same structure as that of the gate trench of the trench-gate MOSFET.

6. The semiconductor device of claim 1, wherein the trench of the JFET is filled with a dielectric layer.

7. The semiconductor device of claim 6, wherein the dielectric layer and the gate dielectric layer include silicon dioxide and the gate conductive layer includes polysilicon.

8. The semiconductor device of claim 3, wherein the trench-gate MOSFET comprises a body contact region of the second conductivity type formed in the body region, and wherein the body region is coupled to a source metal via the body contact region.

9. The semiconductor device of claim 1, wherein the semiconductor device comprises a plurality of the trench-gate MOSFETs and a plurality of the vertical JFETs.

10. A method for fabricating a semiconductor device, comprising:
forming a gate trench of a trench-gate MOSFET and forming a trench of a vertical JFET in a semiconductor layer of a first conductivity type;
forming a doped region of the vertical JFET surrounding and contacting a bottom of the trench of the vertical JFET, wherein the doped region has a second conductivity type opposite to the first conductivity type;
forming a gate region of the trench-gate MOSFET by filling the gate trench with a gate dielectric layer and a gate conductive layer, and forming a gate region of the vertical JFET by filling the trench of the vertical JFET;
forming a source region of the first conductivity type of the trench-gate MOSFET and a source region of the first conductivity type of the vertical JFET in the semiconductor layer;
forming a drain region of the first conductivity type of the trench-gate MOSFET and a drain region of the first conductivity type of the vertical JFET in the semiconductor layer; and
electrically coupling the gate region of the vertical JFET to the source region of the trench-gate MOSFET in the semiconductor layer.

11. The method of claim 10, wherein,
the semiconductor layer comprises a substrate having a heavy dopant concentration of the first conductivity type and an epitaxial layer having a light dopant concentration of the first conductivity type formed on the substrate; and wherein
the step of forming the source region of the vertical JFET comprises forming a doped source region of the first conductivity type at a topside of the epitaxial layer; and wherein
the step of forming the source region of the trench-gate MOSFET comprises:
forming a body region of the second conductivity type adjacent to the gate region of the trench-gate MOSFET in the epitaxial layer, wherein the body region at least partially overlaps the gate region of the vertical JFET; and
forming the doped source region at a topside of the body region.

12. The method of claim 10, wherein the first conductivity type is N type and the second conductivity type is P type.

13. The method of claim 10, wherein, filling the trench of the vertical JFET and the gate trench of the trench-gate MOSFET are proceeded in a same process.

14. The method of claim 10, wherein, filling the trench of the vertical JFET comprises filling dielectric materials in the trench of the vertical JFET.

15. The method of claim 10, wherein, filling the trench of the vertical JFET comprises filling a dielectric material and a conductive material in the trench of the vertical JFET.

16. The method of claim 11, further comprising forming a body contact region of the second conductivity type in the body region of the trench-gate MOSFET.

17. The semiconductor device of claim 14, wherein, the dielectric materials and the gate dielectric material include silicon dioxide, the gate conductive material includes polysilicon.
